(19) United States
(12) Patent Application Publication
(10) Pub. No.: US 2002/0066905 A1
(43) Pub. Date: Jun. 6, 2002

(54) Wing-shaped surface mount package for light emitting diodes

(76) Inventors: Bily Wang, Hsin-Chu (TW); Bill Chang, Hsin-Chu (TW)

Correspondence Address: Hung Chang LIN, 8 Schindler Court, Silver Spring, MD, 20903, US

(21) Appl. No.: 10/051,923

(22) Filed: Jan. 22, 2002

Related U.S. Application Data
(63) Continuation-in-part of application No. 09/982,370, filed on Oct. 19, 2001.
(63) Continuation-in-part of application No. 09/595,907, filed on Jun. 20, 2000.

(51) Int. Cl. H01L 33/00

(52) U.S. Cl. 257/91; 257/433; 257/783; 257/98

(57) ABSTRACT

The bottom metal contacts of a surface mount LED are extended wider than the glue covering the LED. The extensions provide more area for soldering to a motherboard. The glue contains material to change the color of the light emitted from LED to be different from that emitted from the LED. Colorless light can be emitted when blue or UV LED is used.

This is a continuation-in-part application of U.S. patent application Ser. No. 09/982,370, filed Oct. 19, 2001, now pending and copending with patent application of U.S. Ser. No. 09/595,907 now pending and allowed.

### BACKGROUND OF THE INVENTION

(1) Filed of the Invention

The invention relates to light emitting diodes (LED), particularly to surface mount LED package.

(2) Brief Description of the Related Art

Prior art surface mount LED packages, as shown in FIGS. 1,2 and disclosed in Taiwan Patent Application No. 089109999 and co-pending U.S. patent application Ser. No. 09/596,907, have only single-side bottom metal exposed for making contact to a motherboard. The metal contact plates 11, 12 are covered with glue 15 on top as shown in FIG. 2. The metal plates 11,12 have recesses 14 along the vertical edges as shown in the top view FIG. 1, and also have recesses 17 along the horizontal bottom surfaces of the metal contact plates 11, 12 as shown in FIG. 2. These recesses are for sealing glue to lodge and the hold the structure together. The LED 10 is mounted on the first metal contact plate 11. The top electrode of the LED 10 is wire-bonded to the second metal contact plate 12 by wire 13.

As shown in the cross-sectional view FIG. 2 along the section A-A′ in FIG. 1, the glue 15 fills up the recesses 17 at the bottom surface of the package and the recess 14 along the vertical sides of the package to solidify the structure. This structure only exposes the bottom surfaces of metal contact plates 11, 12 not occupied by the recesses for soldering purpose. This limited area for soldering reduces the reliability of the contact.

### SUMMARY OF THE INVENTION

An object of this invention is to improve the reliability of soldering of a surface mount LED package to a motherboard. Another object of this invention is to increase the soldering area of a surface mount LED package to a motherboard.

These objects are achieved by adding extensions to the metal contacts beyond the borders of the glue covering the LED. The extension provides more areas for the contact to be soldered to a motherboard.

### BRIEF DESCRIPTION OF THE SEVERAL VIEWS OF THE DRAWINGS

FIG. 1 shows the top view of a prior art LED package.

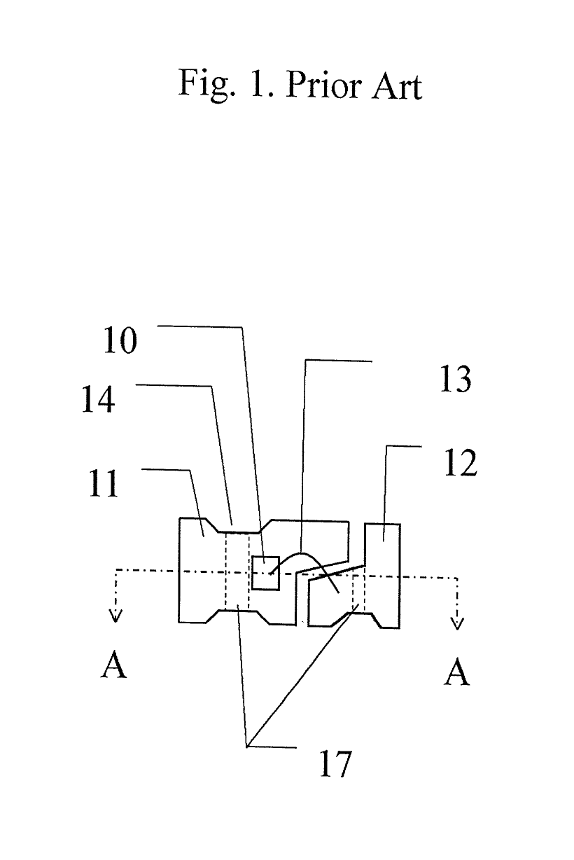

FIG. 2 shows the cross-sectional view of FIG. 1.

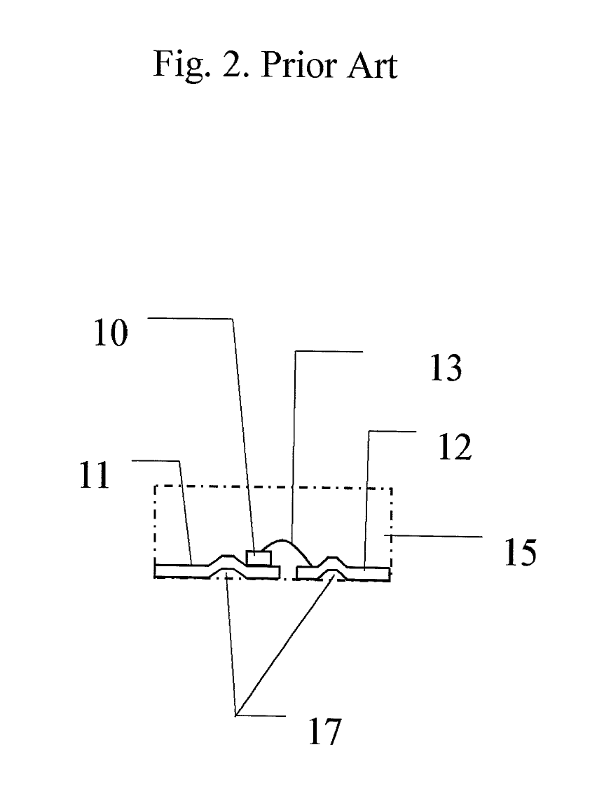

FIG. 3 shows the wing-shaped contacts of the present invention.

FIG. 4 shows the covering of the solder over the contact extensions.

FIG. 5 shows the glue covering the bottom surfaces of the contacts.

FIG. 6 shows the glue covering up to the bottom surfaces of the contacts.

FIG. 7 shows the bottom contacts with rectangular recesses.

FIG. 8 shows the bottom contacts with polygonal recesses.

FIG. 9 shows the glue covering below the bottom surfaces of the contacts.

FIG. 10 shows through holes in the contact metals for the glue to flow through and solidify.

FIG. 11 shows roughened surfaces of the contact metals for increasing the gluing area.

FIG. 12 shows a cup shape metal for focusing the light from the LED.

FIG. 13 shows a package for mounting a LED with two top electrodes.

FIG. 14 shows a package for mounting a LED with two bottom electrodes.

FIG. 15 shows a package having sealing glue containing fluorescent or other modification material to change the color of the light emitted from the LED.

### DETAILED DESCRIPTION OF THE INVENTION

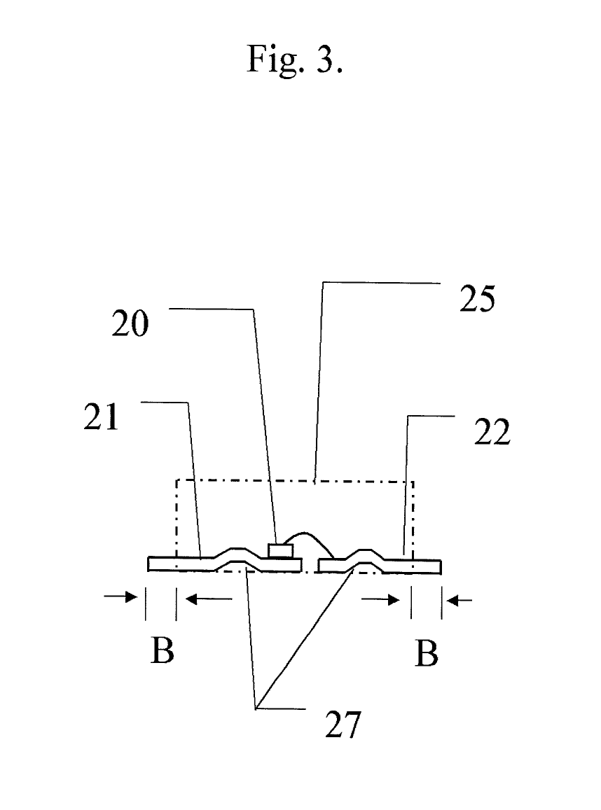

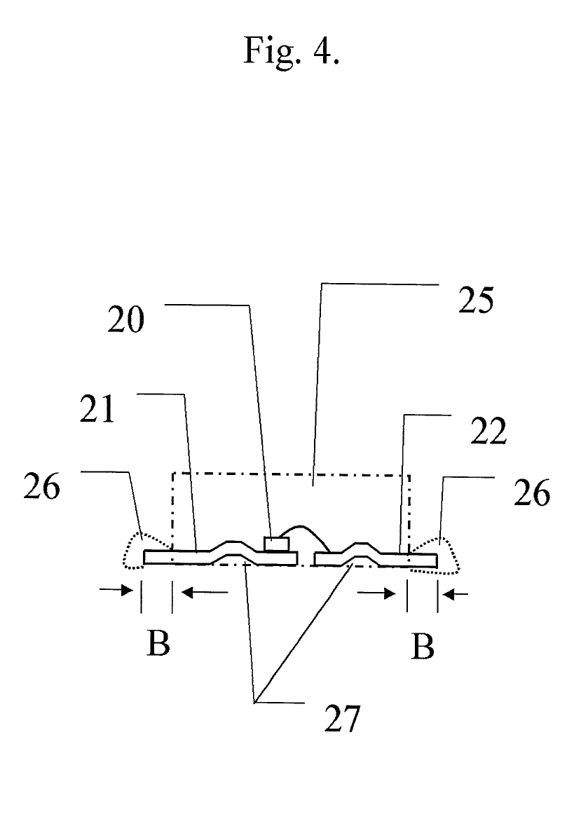

FIG. 3 shows the basic structure of the present invention. A LED 20 with a bottom electrode is mounted on a contact metal plate 21 serving as first terminal. The top electrode of the LED 20 is wire-bonded to a second contact metal plate 22. The contact metal plates, 21, 22 have recesses 27. The LED 20 and a portion of the top surface of the metal content are covered and sealed with glue 25, leaving extensions B of the metal plate 21, 22 uncovered. During sealing, the glue also fills the recesses 27 to solidify the sealed structure. The extensions B extend outside the sealed area, and allow more soldering area 26 for making contacts to a motherboard as shown in FIG. 4. Thus, the solderability of the contacts to a motherboard is improved.

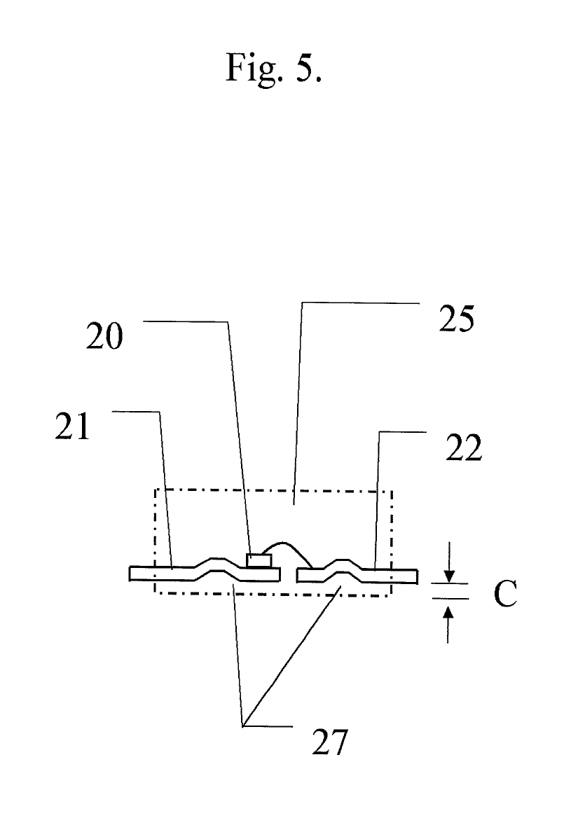

FIG. 5 shows a second embodiment of the invention. The structure is similar to FIG. 4 except that the glue 25 seals below the bottom surfaces of the metal plates 21, 22 by a depth C. Thus the structure is more fully sealed by the glue 25. The extensions beyond the sealed area remains available to be soldered to a motherboard.

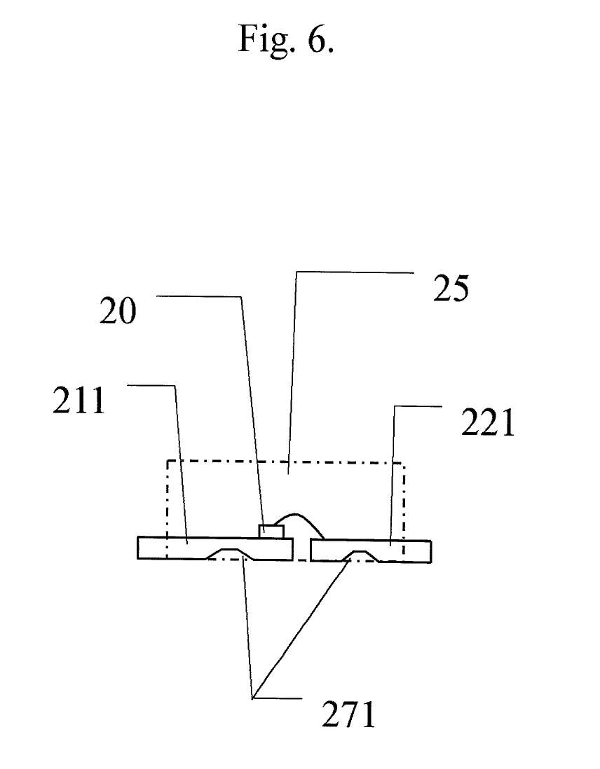

FIG. 6 shows a third embodiment of the invention. The structure is similar to FIG. 3 except that the top surfaces of the metal contact plates 211, 221 are flat. The bottom recesses 271 of such a structure can be fabricated by chemical or machine etching.

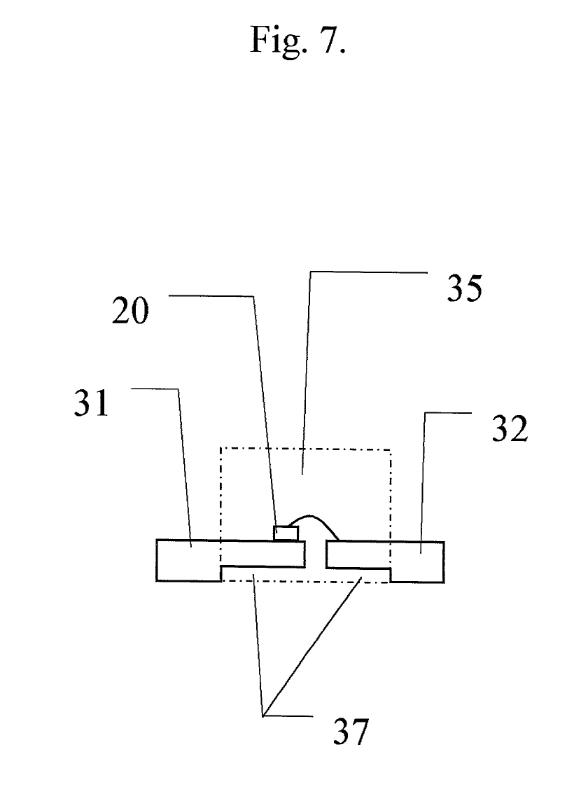

FIG. 7 shows a fourth embodiment of the present invention. The structure is similar to FIG. 6, except that the recess 37 at the bottom of the metal plates 31, 32 is rectangular in shape. The rectangular recess 371 holds more glue 35 to further solidify the structure.

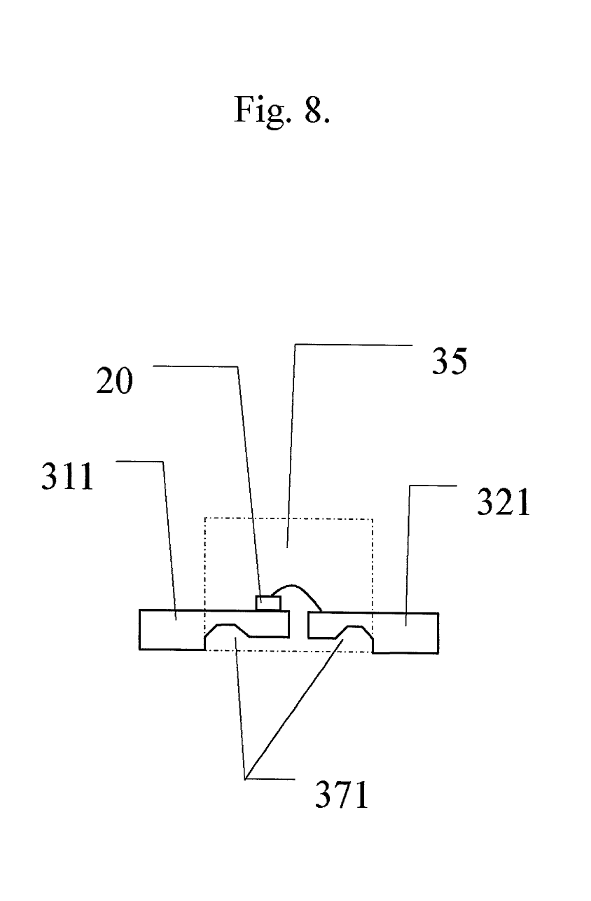

FIG. 8 shows a fifth embodiment of the present invention. The structure is similar to FIG. 6, except that the recess 371 at the bottom of the metal plates 311, 321 is of polygonal shape. The polygonal recess 371 holds more glue 35 to further solidify the structure

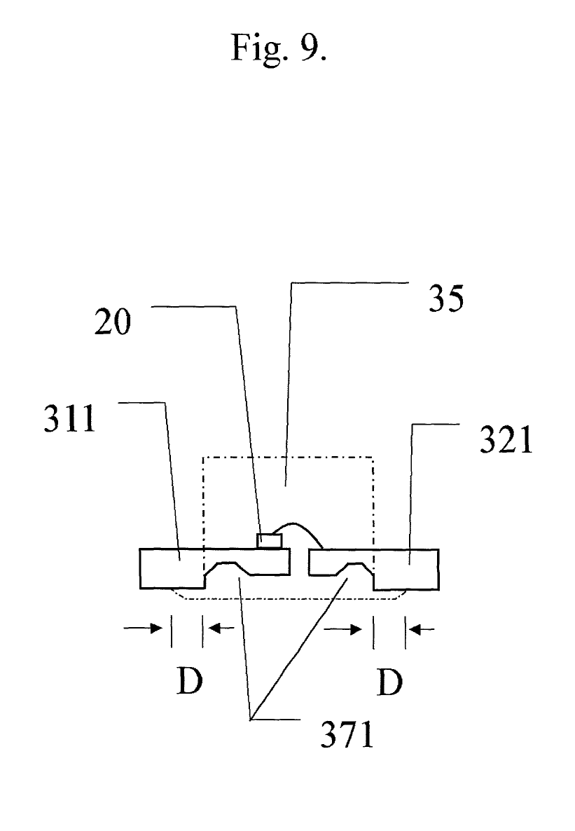

FIG. 9 shows a sixth embodiment of the present invention. . The structure is similar to FIG. 8, except that the glued area below the recesses 371 at the bottom of the metal plates 311,321 is made wider than the width of the glued area 35 on top of the over the LED 20. The extra widths D outside the recess 371 area increase the distance between the soldering spots on a motherboard, thus avoiding the likelihood of short-circuiting between solders.

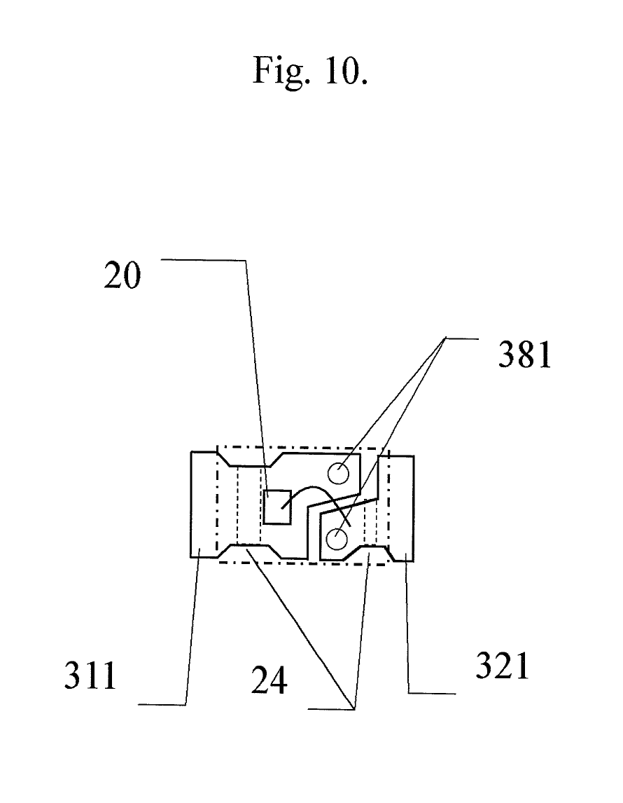

FIG. 10 shows a seventh embodiment of the invention. The structure is similar to FIG. 3, except that two through holes 381 are inserted from the top surfaces of the metal plates 321, 311 to the bottom recess 27 (not shown). The through holes allow glue 25 to flow into the through holes 381, thus further solidifying the structure.

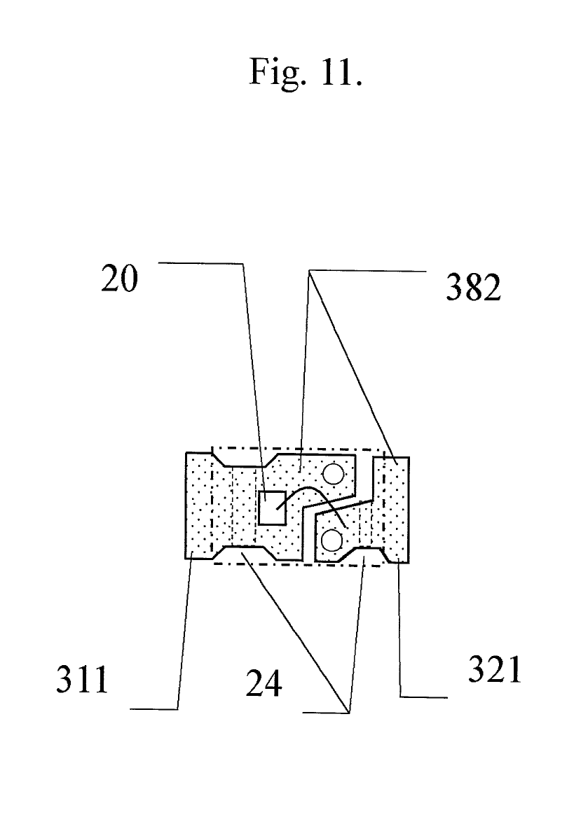

FIG. 11 shows an eighth embodiment of the invention. The structure is similar to FIG. 10, except that the top surfaces 382 of the metal plates 311, 321 are roughened. The roughened surfaces increase the grip of the glue to the structure to further solidify the structure.

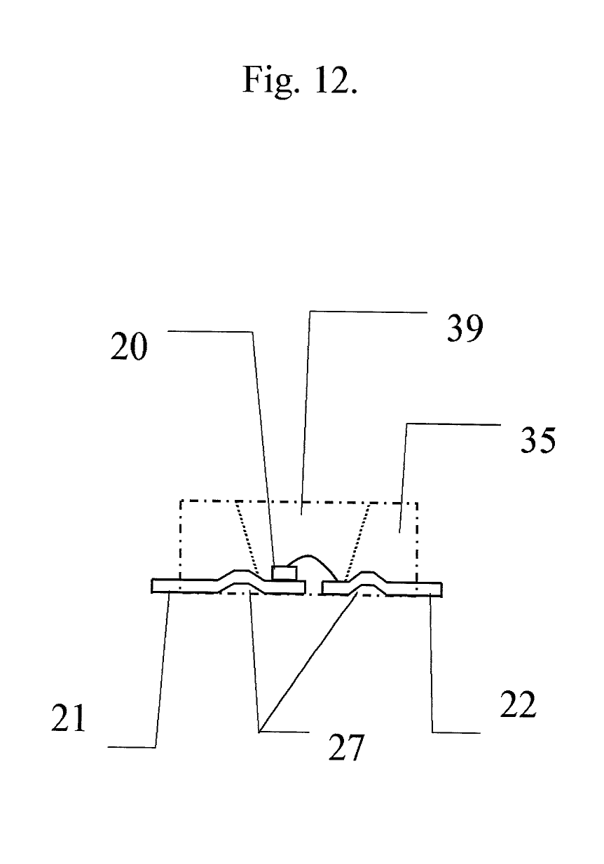

FIG. 12 shows a ninth embodiment of the invention. The structure is similar to FIG. 3, except that the glue 35 on top of the metal plates 21, 22 forms a cup 39 to expose the LED 20. The cup surface help focus the light emitted from the LED 20.

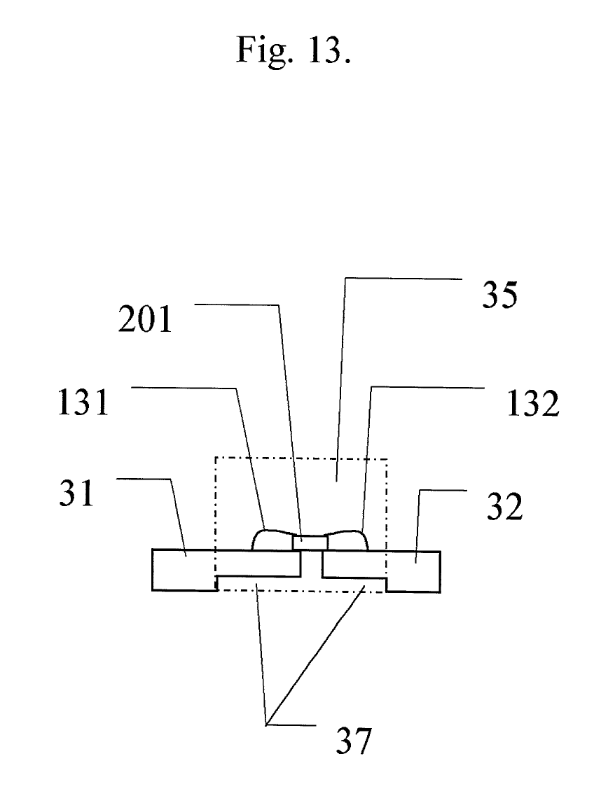

FIG. 13 shows a tenth embodiment of the present invention. The structure is similar to FIG. 8, except that the LED 201 has two top electrodes. The LED 201 straddles over the metal plates 31, 32 and is wire-bonded to these plates respectively by wires 131 and 132.

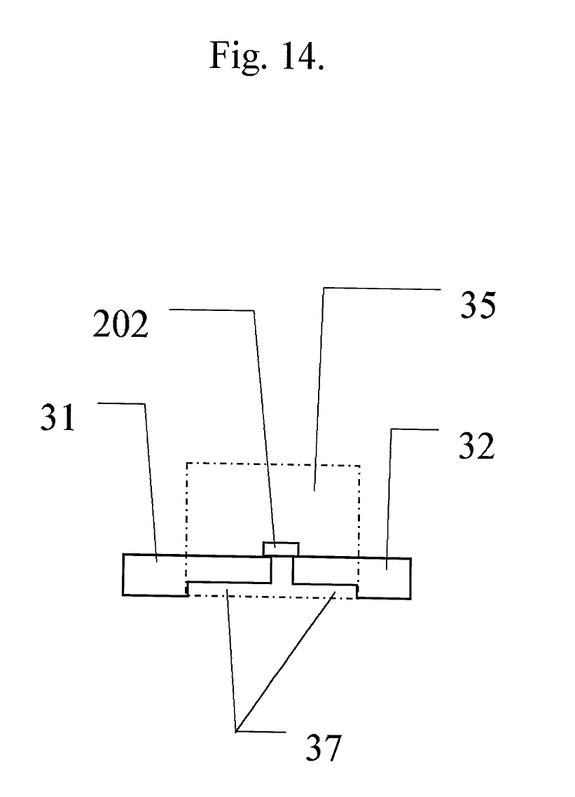

FIG. 14 shows an eleventh embodiment of the invention. The structure is similar to FIG. 8, except that the LED 202 has two bottom electrodes. The LED straddles over and are bonded to the metal plates 31, 32.

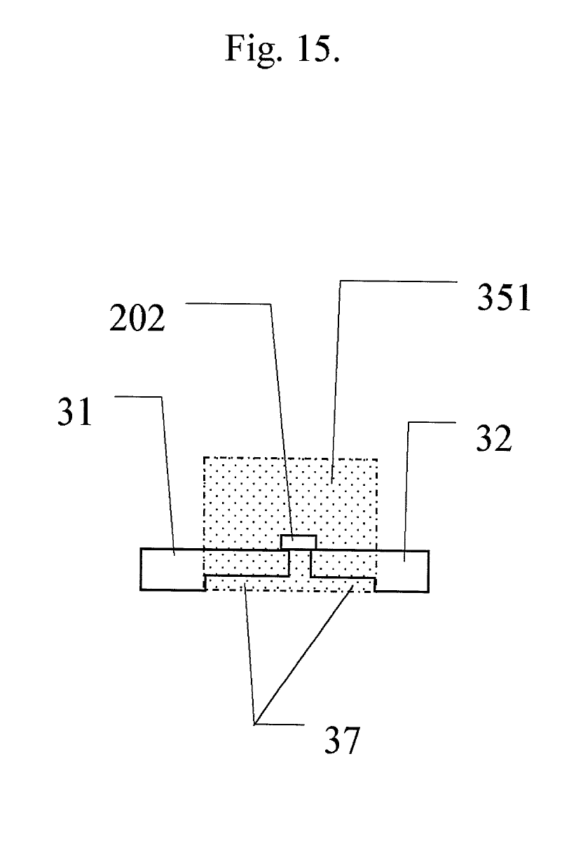

FIG. 15 shows a twelfth embodiment of the invention. In this embodiment, the sealing glue 351, corresponding to glue 25 in FIGS. 3-6 and glue 35 in FIGS. 7-9 and 12-14, contains fluorescent material, decorative material or other color modification material. When the LED is excited, the added material can modify or filter the light emitted from the LED, thereby changing of the color of the light emitted from the package. The fluorescent material can be used to emit colorless light from the package when a blue or UV LED chip is excited.

While the preferred embodiments of the invention have been described, it will be apparent to those skilled in the art that various modifications may be made in the embodiments without departing from the spirit of the present invention. Such modifications are all within the scope of this invention.

1. A surface mount light emitting diode (LED) package, comprising:
a light emitting diode having a first electrode and a second electrode,
a first metal contact plate having a first bottom recess, mounted with said LED and connected to said first electrode;
a second metal contact plate having a second bottom recess and connected to said second electrode;
a glue containing a material to change the color of the light from said package to be different from that emitted from said LED and covering said LED, said first bottom recess and a portion of the top surface of said first metal contact plate, said second bottom recess and a portion of the top surface of said second metal contact plate; and
extensions of said first metal contact plate and said second metal contact plate outside the borders of said glue to provide contact and soldering areas to a motherboard.

2. The surface mount LED package as described in claim 1, wherein the glue covers below the bottom surfaces of said first contact metal plate and of second contact metal plate.

3. The surface mount LED package as described in claim 1, wherein the top electrode of the LED is wire-bonded to said second metal contact plate.

4. The surface mount LED package as described in claim 1, wherein the top surface of said first metal contact plate and the top surface second metal contact plate are flat.

5. The surface mount LED package as described in claim 1, wherein said first recess and said second bottom recess are of trapezoidal shape.

6. The surface mount LED package as described in claim 1, wherein said first bottom recess and said second bottom recess are of rectangular shape.

7. The surface mount LED package as described in claim 1, wherein the fist bottom recess and said second bottom recess are of polygonal shape.

8. The surface mount LED package as described in claim 7, wherein the portion of the glue covering said first bottom recess and said second bottom recess is wider the portion of the glue covering the top surfaces of the first metal contact plate and the second metal contact plate.

9. The surface mount LED package as described in claim 1, wherein the first metal contact plate and the second metal plate each have through holes for said glue to deposit.

10. The surface mount LED package as described in claim 1, wherein the top surface of said first metal contact plate and the top surface of said second metal contact plate are roughened to increase the grip of the glue.

11. The surface mount LED package as described in claim 1, wherein the glue on top of the first metal contact plate and the second metal contact plate are shaped in the form of a cup to expose the LED and to focus the light emitted from the LED.

12. The surface mount LED package as described in claim 1, wherein the first electrode and the second electrode of said LED lie on top of the LED and wire bonded to said first metal contact plate and said second metal contact plate respectively.

13. The surface mount LED package as described in claim 1, wherein said fist electrode and said second electrode are at the bottom surface of said LED and straddles over said first metal contact plate and said second metal contact plate.

14. The surface mount LED package as described in claim 1, wherein said material is a fluorescent material.

15. The surface mount LED package as described in claim 14, wherein a blue LED chip is used to emit colorless light from said package.

16. The surface mount LED package as described in claim 14, wherein a UV LED chip is used to emit colorless lightt from the package.
